(19) United States
(12) Patent Application Publication
(10) Pub. No.: US 2016/0118016 A1
(43) Pub. Date: Apr. 28, 2016

(54) PORTABLE DIGITAL SIGN SYSTEM

(71) Applicant: Anthony DiPrizio, Philadelphia, PA (US)

(72) Inventor: Anthony DiPrizio, Philadelphia, PA (US)

(21) Appl. No.: 14/924,703

(22) Filed: Oct. 27, 2015

Related U.S. Application Data
(60) Provisional application No. 62/069,267, filed on Oct. 27, 2014.

(51) Int. Cl. G09G 5/00; H03K 17/96; H02J 7/00; H05K 7/02

(52) U.S. Cl. CPC G09G 5/003; H05K 7/026; H03K 17/96; H02J 7/0052; G09G 2370/16

(57) ABSTRACT

A portable sign includes a frame, a digital display supported by the frame, a power supply to provide electricity to the digital display, and a controller to initiate a presentation of digital content on the display. The display that is interactive, lightweight and durable. The portable sign may display and collect data The portable sign may be one of a number of portable signs networked to a host device.

### I. CLAIM OF PRIORITY

This application is a continuation patent application of, and claims priority from, U.S. Provisional Patent Application Ser. No 62/069,267, filed on Oct. 27, 2014, which is incorporated by reference herein in its entirety for all purposes.

### II. FIELD OF THE DISCLOSURE

The disclosure relates to signs, and more particularly, to signs that include a digital display.

### III. BACKGROUND

Signage remains an effective way to advertise. Portable signs, in particular, communicate information while placed at a well-traveled location or at a property associated with content of the sign. A passerby can read the information printed on the sign for as long as the sign remains at the location.

### IV. SUMMARY OF THE DISCLOSURE

According to a particular embodiment, a portable sign includes a frame, a digital display supported by the frame, a power supply to provide electricity to the digital display, and a controller to initiate a presentation of digital content on the display.

The sign may include a memory to store the digital content and a second digital display supported by the frame. The controller may be configured to communicate with a network that receives information from a plurality of portable signs. The information includes one or more of: consumer tracking data, weather data, power status data, video data, digital images, recorded audio, and data input by a user via an interface.

The portable sign may include global positioning system circuitry, in addition to a wireless receiver and a wireless transmitter. Photographic and video recording circuitry may be incorporated. The digital content may include video commercial content. The controller is configured to output a result in response to data collected using the digital sign.

An embodiment of the portable sign may include a microphone and a speaker. The portable sign may include a radio frequency identification circuitry and a touch screen interface. The portable sign may include weatherproof material and anti-glare material.

An embodiment of the digital sign may include security circuitry. The security circuitry may initiate one or more of: alerting a user; rendering the display unusable, and tracking a location of the display.

The power supply may include one of: wireless charging circuitry, a battery, a rechargeable battery, and a power cord. The power supply may include solar material attached to the display, such as a panel or a film.

These and other advantages and features that characterize embodiments are set forth in the claims annexed hereto and forming a further part hereof. However, for a better understanding of the invention, and of the advantages and objectives attained through its use, reference should be made to the Drawings and to the accompanying descriptive matter in which there are described exemplary embodiments.

### V. BRIEF DESCRIPTION OF THE DRAWINGS

FIG. 1 is a perspective view of a portable digital sign in accordance with an embodiment;

FIG. 2 is block diagram of a portable digital sign in accordance with another embodiment; and

FIG. 3 is a block diagram of a plurality of portable digital signs networked to a central server.

### VI. DETAILED DESCRIPTION

An embodiment of a portable sign includes a digital, interactive display that is lightweight and durable. The portable sign may display and collect data. The portable sign may be one of a number of portable signs networked to a host device. The portable sign may present audio and visual messages relating to a promotion of a home for sale, consumer product advertising, as well as weather and other local alerts.

A digital display may include liquid-crystal display (LCD), light-emitting diode (LED), plasma, organic light-emitting diode (OLED), and projection technologies, among others. A controller may manage content that is to be played back or otherwise displayed. A power supply and other components may be contained in an housing that protects them from inclement weather. A frame with a handle may support all of the components.

An embodiment of the portable sign may include global positioning satellite (GPS) and wireless connectivity. Near field communication (NFC), radio-frequency identification (RFID), infrared (IR), Bluetooth, speakers, anti-glare screens, touchscreens, mobile phone interaction, and camera technology may be supported.

In an example where a portable sign is used to promote an open house, the portable sign may show photographs of the interior and exterior of a home, in addition to movies of a virtual tour and contact information.

The portable sign may be display information on both sides, although three and four sided signs may be used. The displays may present different data. For instance, one display may prompt user input and stream video data, while another display presents static digital image content.

The portable sign may be used for multiple purposes. For example, a portable sign may display an advertisement for products in a portion of the display screen that is concurrently or alternatively showing photos of a house that is for sale.

A camera and other interfaces may be used to gather tracking data. Illustrative tracking data may include audience data. For instance, the portable sign may track how many people looked at the sign. Tracking data may include demographic information about the people viewing the sign (e.g., sex, age, ethnicity, etc.). Tracking data of another embodiment may detect and count how many cars passed by. The sign could thus replace conventional counters used to track traffic. The controller could further be used to identify and account for vehicles that repeatedly pass by.

In another example, a portable sign may facilitate a secure entry into a home. The portable sign may generate a code, such as a quick response code or another authentication technology credential, including a pin, a password, a cry etc., that is scanned at a door of a home in order to allow access. The authentication credential may allow access for a short period of time. The portable sign may also allow for the capture of how many people actually visit the home. The collected data may be used to create a predicative analytical assessment on how to further promote the home. For instance, the controller may access data models or other stored data used to correlate the gathered data to suggestions and other analysis for selling the home.

A network of portable signs may provide and receive information to and from a central server. The central server may be interfaced via browser. For instance, a real estate company may have hundreds of homes for sale. A virtual map of GPS enabled portable signs may be displayed via the browser. The agency may dynamically update and push content to each of the portable signs. Examples of the pushed data may include new photos, videos, contact information, price reductions, and new audio, among others. The updates may be pushed via single action using the browser.

The portable signs may report information about themselves to a user. Temperature, humidity, and power status may all be reported to indicate an overall operating health of the portable sign(s).

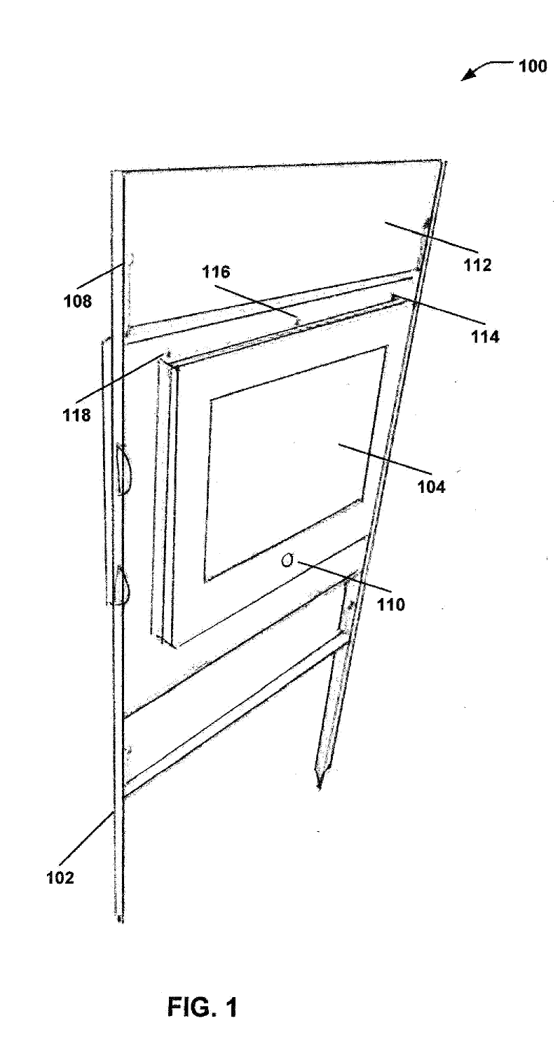

Turning more particularly to the Drawings, FIG. 1 is a perspective view of a portable sign 100 that includes a frame 102 and a digital display 104. The portable sign 100 further includes a power supply (not shown) to provide electricity to the digital display 104, and a controller (not shown) to initiate a presentation of digital content on the display 104.

The digital display 104 may be touchscreen activated and may include LCD, LED, OLED, and projection technologies, among others. The digital display may include one or more screens. Each screen may show different content. Different content may further be shown on a single screen concurrently. For example, a window portion of the screen may show first content, while another window portion displays second content).

An antenna 108 may provide wireless communications between the portable sign 100 and another device. The communications may include data downloaded to the portable sign 100, as well as data collected and uploaded by the portable sign 100.

A camera 110 may be included to capture the data. As discussed herein, the camera 110 may capture photographs or video recordings. The frame 102 supports a static sign 112, such as a message may be printed upon.

A sensor 114 may detect the presence of a person or an object. Examples of a proximity sensor 114 may include RFID.

A microphone 116 and a speaker 118 may also be included in the digital sign 100.

The display 104 may be coated with an anti-glare material. Solar harvesting panels or film may be included on the portable sign 100. In a particular embodiment, a solar harvesting film may cover at least part of the display 104 or the frame 102. The portable sign 100 may provide a Wi-Fi hot spot and a charging port for mobile devices. The portable sign 100 may include a second display (not shown) opposite the digital display 104

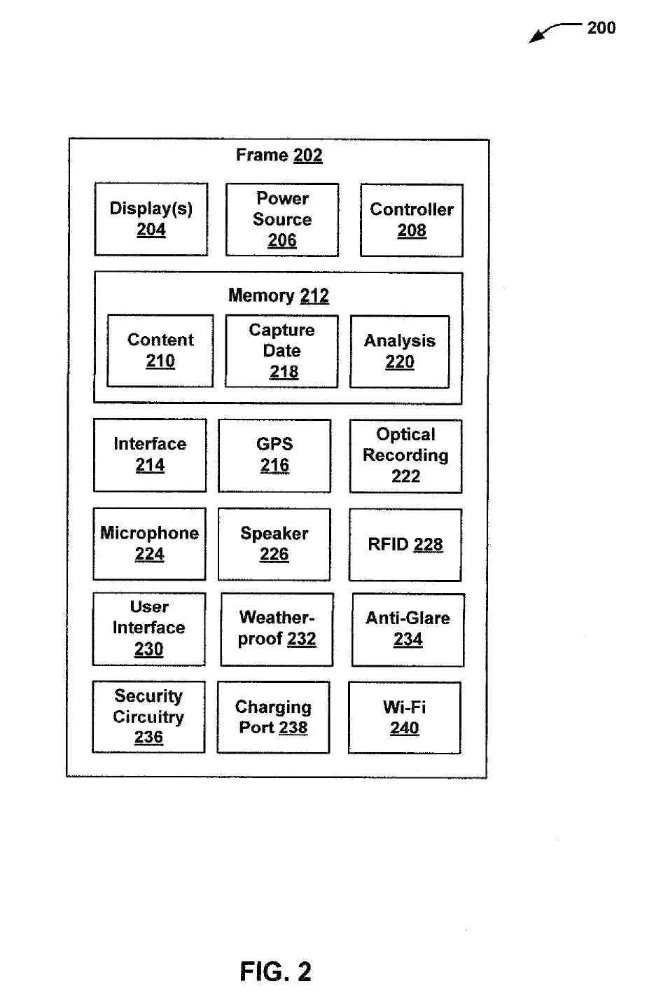

FIG. 2 is a block diagram of portable sign 200 in accordance with a particular embodiment. The portable sign 200 includes a frame 202 and one or more digital displays 204. A power supply 206 may provide electricity to the digital display(s) 204. A controller 208 initiates a presentation of content 210 on the digital display(s) 204.

The portable sign 200 may include a memory 212 to store the content 210. The controller 208 may be configured to communicate with a network (not shown) or other device using an interface 214. The information, or capture data 218, may include one or more of: consumer tracking data, weather data, power status data, video data, digital images, recorded audio, and data input by a user.

The portable sign 200 may include GPS circuitry 216, in addition to a wireless receiver and a wireless transmitter (e.g., shown in FIG. 2 as included in the interface 214. Photographic and video recording circuitry, shown as optical recording circuitry 222, may be incorporated. The content 208 may include video commercial content. The controller is configured to output analysis 220 in response to data collected using the portable sign 200.

An embodiment of the portable sign 200 may include a microphone 224 and a speaker 226. The portable sign 200 may include RFID circuitry 228 and a user interface 230, which may include a touch screen interface. The portable sign 200 may include weatherproof material 232 and anti-glare material 234.

An embodiment of the portable sign 200 may include security circuitry 236. The security circuitry 236 may initiate one or more of: alerting a user; rendering the portable sign 200 unusable, and tracking a location of the portable sign 200. In another example, the security circuitry 236 may be used to authenticate a user based on presented user input to the portable sign 200. The authentication may be used to gain entry into a building or to access information stored on in the memory 212 or at a remote server (not shown).

The power supply 206 may include one of: wireless charging circuitry, a battery, a rechargeable battery, and a power cord. The power supply 206 may include solar material attached to the display, such as a panel or a film. The portable sign 200 may include a charging port 238 for plugging in and recharging devices, as well as a Wi-Fi hotspot 240.

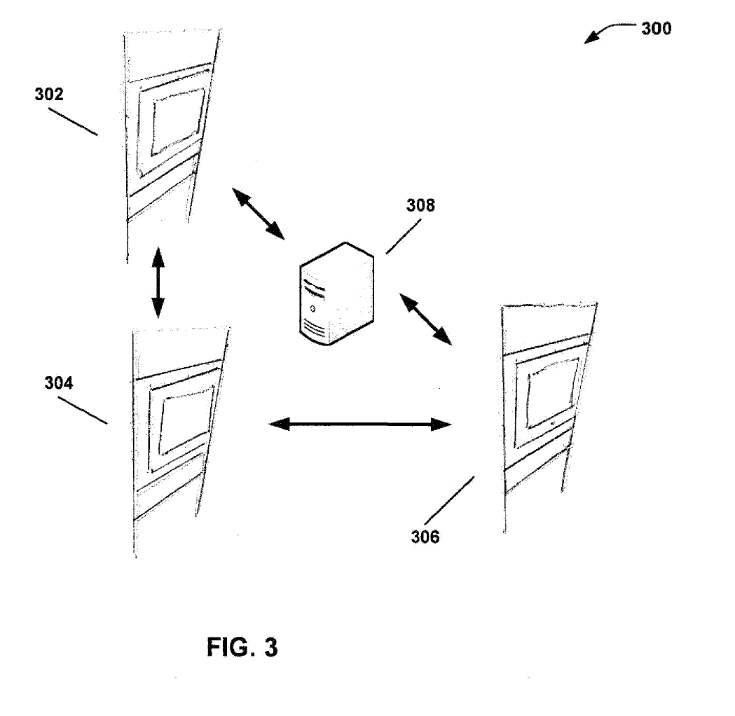

FIG. 3 is a diagram illustrating a networked system 300 of a plurality of portable signs 302, 304, 306 that are in communication with a central server 308. According to a particular embodiment, the portable signs 302, 304, 306 are additionally or alternatively in communication with one another.

A user may push information to each portable sign 302, 304, 306 from the central server 308. As discussed herein, the portable signs 302, 304, 306 may provide information to the central server 308. The central server 308 may be accessed by a user to ascertain information about the portable signs 302, 304, 306. For example, a user may ascertain information about the operating health of each sign 302, 304, 306, or demographic information or comments input and pertaining to persons viewing a portable sign 302, 304, 306. Analysis of input data may be performed at the central server 308 and/or at each portable sign 302, 304, 306.

Those skilled in the art may make numerous uses and modifications of and departures from the specific apparatus and techniques disclosed herein without departing from the inventive concepts. Consequently, the disclosed embodiments should be construed as embracing each and every novel feature and novel combination of features present in or possessed by the apparatus and techniques disclosed herein and limited only by the scope of the appended claims, and equivalents thereof.

1. A portable sign, comprising:
a frame;
a digital display supported by the frame;
a power supply to supply electricity to the digital display; and
a controller to initiate a presentation of digital content on the display.

2. The portable sign of claim 1, further comprising a memory to store the digital content.

3. The portable sign of claim 1, further comprising a second digital display supported by the frame.

4. The portable sign of claim 1, wherein the controller is configured to communicate with a network that receives information from a plurality of portable signs.

5. The portable sign of claim 4, wherein the information includes at least one of: consumer tracking data, weather data, power status data, video data, digital images, recorded audio, data input by a user via an interface.

6. The portable sign of claim 1, further comprising global positioning system circuitry.

7. The portable sign of claim 1, further comprising at least one of a wireless receiver and a wireless transmitter.

8. The portable sign of claim 1, further comprising at least one of photographic and video recording circuitry.

9. The portable sign of claim 1, wherein the controller is configured to output a result in response to data collected using the digital sign.

10. The portable sign of claim 1, further comprising at least one of a microphone and a speaker.

11. The portable sign of claim 1, wherein the controller is used to authenticate a user based on presented user input.

12. The portable sign of claim 1, further comprising radio frequency identification circuitry.

13. The portable sign of claim 1, wherein the display includes a touch screen interface.

14. The portable sign of claim 1, further comprising weatherproof material.

15. The portable sign of claim 1, further comprising anti-glare material.

16. The portable sign of claim 1, further comprising security circuitry.

17. The portable sign of claim 16, wherein the security circuitry, initiates at least one of:
alerting a user; rendering the display unusable, and tracking a location of the display.

18. The portable sign of claim 1, further comprising a charging port for a mobile device.

19. The portable sign of claim 1, wherein the power supply includes at least one of: wireless charging circuitry, a battery, a rechargeable battery, and a power cord.

20. The portable sign of claim 1, wherein the power supply includes solar material attached to the display.
